(19) United States
(12) Patent Application Publication
(10) Pub. No.: US 2011/0239815 A1
(43) Pub. Date: Oct. 6, 2011

(54) DRIVE DEVICE COMPRISING A DRIVE SHAFT AND DRIVING CRANKS

(75) Inventors: Harald Grab, Hannover (DE); Michael Pausch, Oberwerrn (DE)

(73) Assignee: SCHAEFFLER KG, Herzogenaurach (DE)

(21) Appl. No.: 12/599,454

(22) PCT Filed: May 8, 2008
(86) PCT No.: PCT/DE08/00801

§ 371 Date: Nov. 9, 2009

(30) Foreign Application Priority Data
May 10, 2007 (DE) 10 2007 021 972.7

(51) Int. Cl. B62M 3/00; B62M 23/00; G01R 33/02; G01L 3/00; G01P 3/00

(52) U.S. Cl. 74/594.1; 324/252; 73/862.08; 73/509

(57) ABSTRACT

A drive device for a machine, which has a drive shaft that can be rotated about an axis, and two driving cranks which are connected to the shaft in an angularly rigid manner in relation to the axis thereof. In order to determine the torque applied to the drive shaft in a simple and economical manner, the drive device has at least one magnetostrictive body connected to the driving cranks in a fixed manner, and a magnetic field sensor for measuring the magnetic stray field of the magnetostrictive body.

### FIELD OF THE INVENTION

The invention relates to the field of machine engineering and measuring technology and can be applied, in particular, to bicycles, ergometers and Pedelecs.

A variety of mechanical machines, which have a driveshaft, which can be driven directly by means of one or more driving cranks, are conceivable. A particularly prominent role in these applications is played by a bicycle in which the driving power is usually transmitted from the front driveshaft to the shaft of the driven wheel via a ring gear and a chain.

In this context, the front driveshaft is usually driven by means of driving cranks, referred to as foot pedals, via pedals by means of the force of the human legs.

The driving cranks are usually offset by 180° with respect to one another in relation to the rotational axis of the driveshaft, with the result that the driving force is periodically transmitted in an alternating fashion via one of the driving cranks in each case.

In addition, in the higher power range, the cyclist's foot is connected to the driving crank or the pedal by means of an attachment device, with the result that as far as possible a force can be applied during the entire rotation of the driving crank.

It has been known for a long time to measure the rotation speed of the wheels, and therefore at least indirectly also the rotational speed of the driveshaft, by means of various types of devices in order to determine the speed of the bicycle or, for example, the rotational speed of an ergometer.

The measurement of the power and/or of the torque acting on the driveshaft is more difficult. This requires a measurement of force and/or torsion which is basically complex.

Various methods and devices for determining a torsion force, in particular also in conjunction with bicycles, are known from the prior art.

DE 102005023182 A1 presents a torque registering device with a torque transmission plate for transmitting a torque between an engine output element and a torque converter element, wherein the transmission plate can easily be deformed elastically as a result of a torque by virtue of targeted weakened portions, and wherein strain gages for confirming the elastic deformation are provided on deformable webs of the transmission plate. Said document does not contain anything else about the functioning of the strain gages.

DE 102005041287 A1 presents a torque sensor comprising two component shafts, with each of the component shafts being connected to what is referred to as a registering tube and the registering tubes being coaxial to one another. They are permanently connected to the component shafts at points which are spaced apart from one another, and they have circumferential teeth on the end side so that given a greater or lesser degree of rotation of the shaft components, the magnetic resistance between the sensing tubes is periodically changed depending on the correspondence of the teeth. As a result, rotation of the component shafts with respect to one another can be confirmed. This is a measure of the acting torsional forces.

DE 102005006769 A1 presents generally, as a reversal of the magnetostriction, what is referred to as the Villary effect by means of which a magnetic effect of the shaft is generated through deformation, for example as a result of the torsion of a shaft. Iron, copper, nickel or alloys of these metals are referred to as materials which exhibit a Villary effect.

DE 10044701 C1 discloses a transmission device on the pedals of a bicycle, by means of which the pedal force is transmitted to the foot pedal. An elastic element in the form of a spring is compressed by the transmission force, and this force effect is measured in order to determine the transmitted torque therefrom.

DE 69900898 T2 discloses the application of magnetostrictive elements for measuring torsion, wherein a magnetic material is intended to convert the torsion into an electrical voltage.

Against this background, the object of the present invention is to find a way which is as structurally simple and cost-effective as possible of determining the torque acting on the driveshaft in a drive device for a machine comprising a driveshaft which can be rotated about an axis, and comprising two driving cranks which are connected to the latter in an angularly rigid manner in relation to the rotational axis thereof.

The object is achieved according to the invention by means of at least one magnetostrictive body which is permanently connected to one of the driving cranks, and by means of a magnetic field sensor for measuring the magnetic leakage field of the magnetostrictive body.

The torque is transmitted to the driveshaft by driving the driving cranks in the circumferential direction. The driving cranks themselves are subjected to flexural stressing and are connected in an angularly rigid manner to the driveshaft by means of a screwed connection, for example with a crank star or by means of some other joining technique.

Basically, the driving cranks are particularly accessible for measurement, or for the installation of sensors. Given known flexural rigidity, the flexural loading of a driving crank can be determined by means of the flexural deformation which occurs. According to the invention, the latter is shared with a magnetostrictive body which is permanently connected to the driving crank and which is deformed just as much as the driving crank.

Magnetostrictive, usually permanently magnetic, bodies have the property that their magnetic behavior changes when they are deformed. In particular, a permanent magnetic field, which is stable and constant for as long as the body remains undeformed, can be introduced into such a magnetostrictive body. For example, said magnetic field can be configured in such a way that the magnetic flux within the body is closed and therefore a minimized leakage field penetrates to the outside.

If the body is then deformed, the generation of a leakage current can be confirmed outside the body. This can be evaluated after the correction of interference fields which are possibly present, such as for example the Earth's magnetic field, and the deformation of the magnetostrictive body and subsequently the deformation, or the flexural moment which is the cause of the latter and is acting on the crankshaft, can be determined.

The drive device can usually be calibrated by applying a defined flexural moment to the driving crank and measuring the generated leakage magnetic field for various values, and a corresponding measured value table can be stored for evaluation purposes.

As a result, for example in the case of a bicycle, it is possible to determine the torque acting on the driveshaft at a particular time by evaluating a leakage magnetic field in the region of the driving cranks, given knowledge of the distance between the magnetostrictive body and the axle.

An advantageous refinement of the invention provides that a magnetostrictive body is connected to each of the driving cranks.

Monitoring both driving cranks permits the entire acting torque to be determined with a relatively high degree of accuracy. Although it is basically possible to assume equal loading of the two driving cranks, this assumption is not necessarily met in ideal terms. Summing therefore permits a greater degree of accuracy to be achieved than if conclusions were drawn about the entire torque on the basis of merely one-sided measurement on a driving crank. In addition, the asymmetry of the loading can also be determined and evaluated for various purposes.

For example, when the invention is applied in competitive sport it is possible to indicate to a sports cyclist that he is either applying his force unevenly between the foot pedals or that one of his legs is weaker than the other and requires additional training.

The magnetostrictive body can, on the one hand, be integrated into the driving crank by virtue of the fact that it is inserted into a recess in the driving crank and cast or bonded therein, or it is also possible to provide for the magnetostrictive body to be fitted onto the driving crank and permanently connected thereto in such a way that it shares the deformation of the driving crank. This is possible, for example, by means of bonding, soldering or welding.

On the other hand, the integration can also be implemented by virtue of the fact that the magnetostrictive body is connected integrally to the drive crank, as a part thereof, without a joint. In this case, the magnetostrictive body can be magnetized, for example after manufacture of the crank.

The driving cranks then have to be composed of a magnetizable material. Otherwise, they may be composed of other known materials such as, for example, steel, titanium alloys or composite substances or graphite.

Basically, it may also be advantageous to manufacture the driving crank from a magnetically inactive material so that the leakage field which emerges from the magnetostrictive body does not directly enter the material of the driving crank and the flux lines are closed there. It is desirable for the leakage field to be capable of reaching at least to corresponding magnetic field sensors and of being detected there.

The corresponding magnetic field sensors can also be integrated into the driving crank or attached thereto in order to measure the magnetic field effectively. Corresponding measured values can be transmitted in a line-bound fashion, but also by means of a radio link, to an evaluation device.

A further advantageous refinement of the invention provides for a magnetostrictive body to be permanently connected to the driveshaft in a torque-transmitting region.

In this way, it is possible, by means of an additional magnetic field sensor, to determine the torque acting on the driveshaft and to compare it with the partial moment which is applied by means of the respective driving crank.

A further advantageous refinement of the invention provides that magnetostrictive bodies which are integrated into an output element of the driveshaft, in particular into a crank star, are provided.

This makes it possible to sense the overall moment and to generate friction losses, for example in the bearing of the driveshaft, or losses which are generated by forces not oriented in the circumferential direction, on the driving cranks.

It may then also be sufficient to arrange just a single magnetostrictive body in a driving crank and to measure the sum of the torques in the driveshaft, or more easily in an output element, in order to determine the torque acting in the other driving crank, by means of subtraction.

The corresponding magnetic field sensors can either be arranged in the immediate vicinity of the driveshaft or on the driveshaft itself or in the vicinity of the output element in the sphere of influence of the leakage current of the corresponding magnetostrictive sensor.

The invention can also advantageously be developed by an evaluation unit in which a torque is determined from the measured magnetic field strength.

Within the evaluation unit, corresponding torques can be determined by means of a stored formula or by the assignment of torque values in a stored value table from the measured magnetic field strengths. Said values can also be displayed, for example, in a bicycle or ergometer, in order to provide the driver or rider with information about the mechanical loading of the drive device and about the forces which he applies.

For example, this can be used for a warning, since it is usually considered to be more favorable for the human body to train at relatively high rotational speeds and relatively low torques than with high forces which load the skeleton and the joints excessively. Then, if a corresponding torque threshold were exceeded, it would be possible to output a warning which would cause the driver to change a gear speed.

Basically, averaged torque values, which are respectively averaged, for example, over half a rotation of the driveshaft or less, that is to say in a bicycle or ergometer typically over the time period in which the corresponding drive crank is loaded by pressure, should be determined during the evaluation.

It is advantageous here to provide a rotational speed measuring device for determining the rotational speed of the driveshaft.

The rotational speed can also be determined in addition to the torque, with the result that both variables together permit the applied power to be acquired. This can be used either apart or together with the torque, when certain threshold values are reached, to either connect an additional drive of the machine/of the bicycle into the circuit or disconnect it therefrom, or in the case of a bicycle or ergometer it can be used to automatically change the gear speed, or to set a higher or lower load resistance, specifically in the case of an ergometer. A control unit, in which threshold values for acquired torques are stored, and which is connected to an additional drive and/or a switching device for a transmission, is advantageously provided for this purpose.

The control unit can, on the one hand, operate exclusively as a function of the device for determining the torque or additionally can also operate taking into account the rotational speed measured values or the power measured values which are determined therewith.

For this purpose, the evaluation device can also have a power calculating unit.

The invention relates not only to a drive device for a machine but also to a method for operating such a machine as the one described above, wherein the connection and disconnection of an additional drive and/or a switching device are carried out taking into account the torque which is averaged over time and/or the power which is averaged over time.

Finally, the invention also relates to a bicycle, a Pedelec or an ergometer comprising a drive device such as that which has been described above.

The invention will be shown by means of an exemplary embodiment in a drawing, and subsequently described.

In said drawing:

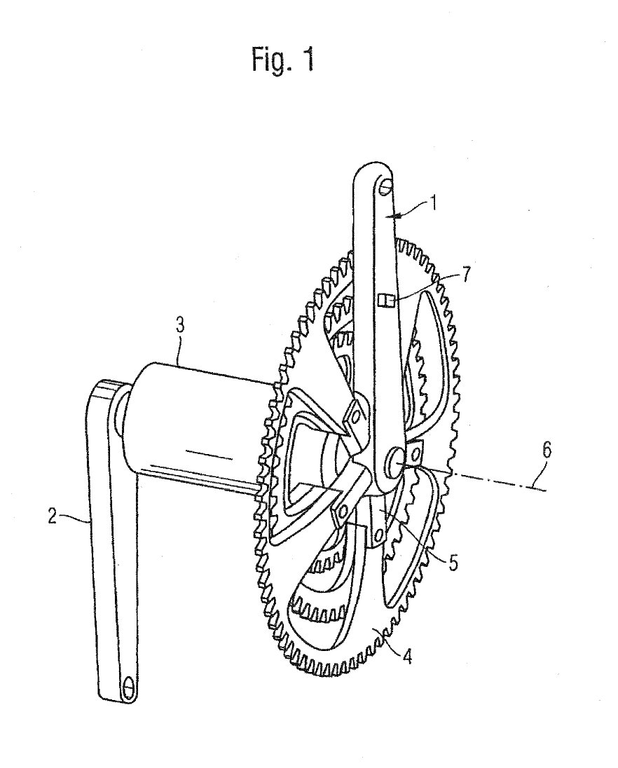

FIG. 1 shows the driveshaft of a bicycle comprising two foot pedals and a chain ring in a perspective illustration;

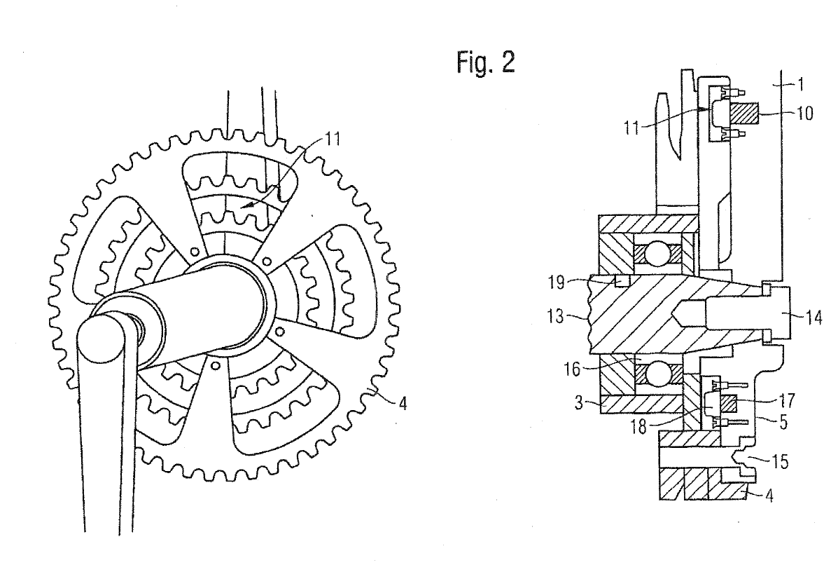

FIG. 2 shows a cross section through part of the driveshaft, a crank star and a driving crank, and a corresponding perspective illustration;

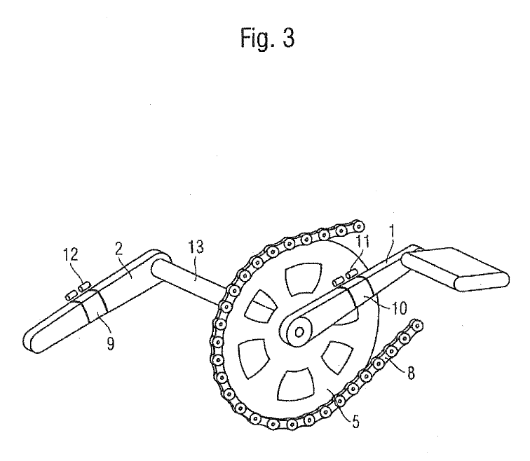

FIG. 3 shows a perspective illustration of a drive device comprising two foot pedals and corresponding magnetostrictive bodies; and

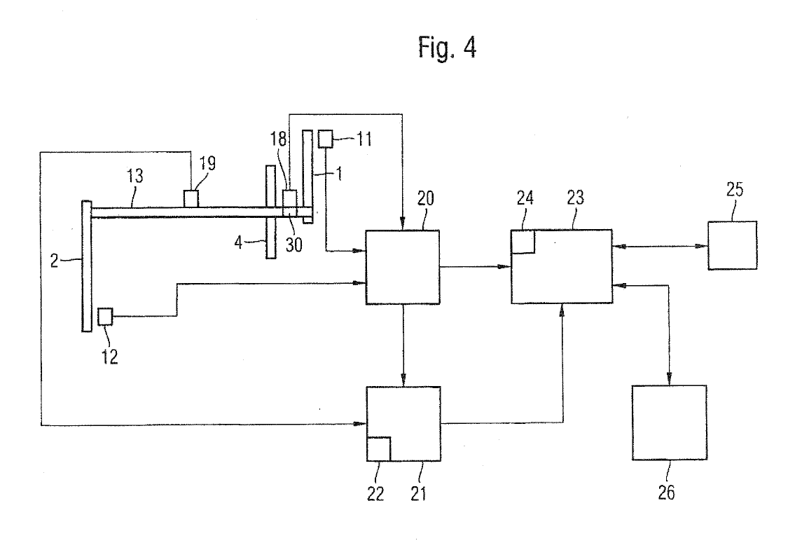

FIG. 4 shows a schematic overview of the functions of the evaluation of the measured values.

FIG. 1 shows, as typical components of a bicycle or ergometer or Pedelec, two driving cranks 1, 2, also referred to as foot pedals in this context, in which the pedals are omitted, and the encapsulation 3 in a driveshaft (not illustrated in the other figures). In addition, a series of ring gears 4 are illustrated, said ring gears 4 being connected to the driveshaft via what is referred to as a crank star 5.

The driving cranks 1, 2 can be connected to the driveshaft in an angularly rigid manner in relation to the axis 6 via, for example, a positively locking connection.

A magnetostrictive body 7 is illustrated on the outside of the first driving crank 1, facing away from the second driving crank.

The magnetostrictive permanently magnetic body is embedded into the material of the driving crank 1 and attached there, for example, by means of soldering.

Such a magnetostrictive body is arranged in the second driving crank 2, but cannot be seen in the figure.

FIG. 2 shows, in an overview illustration, that a chain (not illustrated), which is typically connected to the corresponding pinion on the rear wheel of the bicycle, is driven by means of a ring gear.

The magnetostrictive bodies 9, 10 are illustrated in such a way that they form an integral part of the driving cranks 1, 2.

The magnetostrictive bodies 7, 9, 10 were already magnetized before initial operation, if appropriate even before their installation in the corresponding driving crank. Their leakage magnetic field which penetrates to the outside is ideally minimal by virtue of the fact that as many flux lines as possible are closed within the material of the magnetostrictive body.

One magnetic sensor 11, 12, each is provided outside the respective magnetostrictive body in order to measure the corresponding leakage magnetic field, which magnetic field sensors 11, 12 can be embodied, for example, as conductor coils with or without a ferromagnetic core, and their throughcurrent is monitored.

It is also possible to provide two coils each in one magnetic field sensor in order to provide possible ways of compensating for interference variables such as, for example, the Earth's magnetic field or locally generated interference fields.

If one of the foot pedals 1, 2 is subjected to flexural stressing in order to bring about a torque for the purpose of either accelerating or braking the bicycle or a corresponding machine operated by the driveshaft, the bending of the corresponding driving crank leads to proportional deformation of the respective magnetostrictive body 9, 10 and therefore to a change in the magnetic field, which can be confirmed by means of the magnetic sensors and converted into a flexural moment. From the latter, it is then possible to determine the torque acting on the driveshaft 13.

FIG. 2 shows in more detail the design of the driveshaft and its coupling to the ring gear 4 and the foot pedal 1.

A corresponding longitudinal section is illustrated on the right-hand side of FIG. 2, and the three-dimensional illustration for more precise reference on the left-hand side. The scale on the right-hand side in FIG. 2 is highly enlarged compared to the three-dimensional illustration on the left-hand side.

Firstly part of the driveshaft 13 is illustrated in longitudinal section, which driveshaft 13 is connected further to the second driving crank 2 in the part which is not illustrated. By means of a screwed connection 14, the driving crank 1 is connected in an angularly rigid manner to the shaft 13. The driving crank 1 can be embodied integrally with what is referred to as a crank star 5, onto which the ring gears 4 are screwed on by means of screwed connections 15 distributed over the circumference.

The driving crank 1 is therefore used to apply the torque to the shaft 13, while the crank star brings about the output by transmission to the ring gears 4.

The figure shows a magnetostrictive body 17 which is seated on the crank star and registers a moment at this location. This moment constitutes a partial moment of the entire transmitted moment. Ideally, such a sensor is seated on or in each spoke of the crank star. The sensors can also be integrated into the respective spokes. The sum of the registered torques of these sensors is equal to the overall torque, that is to say to the moment which is transmitted via the chain to the rear wheel, neglecting the loss of efficiency of the chain drive.

The driveshaft 13 is mounted in roller bearings, one of which is denoted by 16 and is surrounded in an overall protective fashion by the housing 3.

FIG. 2 firstly shows a measuring arrangement 10, 11, composed of a magnetostrictive body 10 and a magnetic field sensor 11.

In addition, a further magnetostrictive body 17 and a magnetic field sensor 18, by means of which the output torque can be determined in order to identify the efficiency of the arrangement, is illustrated in the region in which the torque is transmitted from the crank star 5 to the ring gear 4.

In addition, an element 19 of a rev counter, which measures the rotations of the driveshaft 13 and therefore permits the rotational speed to be determined by means of a time measurement, is illustrated.

FIG. 4 basically illustrates the function of the evaluation unit, of a power calculating unit and of a control unit.

FIG. 4 shows the shaft 13 and driving cranks 1, 2 and the magnetic field sensors 11, 12 assigned thereto.

In addition, a magnetic field sensor 18 for registering the output torques at the ring gear 4 is illustrated. The magnetic field sensors 11, 12, 18 are connected to the evaluation unit 20. In the latter, the respective instantaneous torque, which is applied to the shaft, and the sum of the torques are calculated from the corresponding flexural moments, for example. Said sum can be compared with the output torque and an efficiency level can be determined therefrom.

In addition, the torque can be averaged over time, for example, this can also be done individually for the values of the driving cranks 1, 2, in order to determine asymmetries.

It is additionally possible to monitor the maximum acting flexural moment on the driving cranks or the maximum acting torque on the shaft 13, and sliding chronological averages can be formed, for example for a half rotation of the shaft each, in order to calculate the mechanical loading of the drive device, and also the forces acting, for example in the case of a bicycle, on the movement apparatus of the person driving said drive device.

Depending on the threshold values set, both for the maximum forces/moments and for the average values, it is possible to feed corresponding data to a control unit 23 in which threshold values are stored in a memory unit 24 and are compared with the instantaneously measured values. If certain threshold values are exceeded, it is possible, on the one hand, to feed a control instruction to an auxiliary drive device 25, for example in the form of an electric motor, which can be connected into the circuit or disconnected therefrom, and on the other hand a switching device 26 for a transmission can be actuated in order to change the forces in the drive device and at the same time adapt the rotational speeds. For example, the actuation of the switching device 26 can lead to a “lower” gear speed being shifted when there is excessively high torque loading, which gear speed leads, for example, to the selection of a smaller pinion on the ring gear 4.

The figure additionally illustrates a rotational speed sensor 19 which is connected to a power calculating unit 21. In the latter, a rotational speed is calculated from the pulses of the rotational speed sensor 19 by means of a timing unit 22, said rotational speed permitting, together with the data of the evaluation unit 20, a power calculation.

Correspondingly acquired power levels can also be fed to the control unit 23, which can also bring about the actuation of an auxiliary drive 25 or of a switching device 26 as a function of power values when corresponding threshold values are exceeded or undershot.

A torque measurement which can be used for various purposes in monitoring and control operations can be easily carried out by means of the invention in a machine of the type illustrated, for example a bicycle, an ergometer or a Pedelec, if appropriate through retrofitting.

### LIST OF REFERENCE NUMERALS

1, 2 Driving cranks

3 Encapsulation

4 Ring gears

5 Crank star

6 Axis

7, 9, 10, 17 Magnetostrictive bodies

8 Chain

11, 12, 18 Magnetic field sensor

13 Driveshaft

14, 15 Screwed connections

16 Roller bearing

19 Element of a rev counter

20 Evaluation unit

21 Power calculating unit

22 Timing unit

23 Control unit

24 Memory unit

25 Auxiliary drive device

26 Switching device

1. A drive device for a machine, comprising:
a driveshaft which is rotatable about an axis; and
two driving cranks which are connected to the driveshaft in an angularly rigid manner in relation to the axis thereof;
at least one magnetostrictive body, which is permanently connected to one of the driving cranks; and
a magnetic field sensor for measuring a magnetic leakage field of the magnetostrictive body.

2. The drive device of claim 1, wherein the magnetostrictive body is connected to each of the driving cranks.

3. The drive device of claim 1, wherein the magnetostrictive body is integrated into each of the driving cranks.

4. The drive device of claim 1, wherein the magnetostrictive body is bonded onto each of the driving cranks.

5. The drive device of claim 1, wherein the magnetic field sensor is attached to each of the driving cranks.

6. The drive device of claim 1, wherein the magnetostrictive body is permanently connected to the driveshaft in a torque-transmitting region.

7. The drive device of claim 1, further comprising magnetostrictive bodies which are integrated into an output element of the driveshaft.

8. The drive device of claim 1, further comprising an evaluation unit, in which a torque is determined, from a measured magnetic field strength.

9. The drive device of claim 1, further comprising a rotational speed measuring device for determining rotational speed of the driveshaft.

10. The drive device of claim 8, further comprising a control unit in which threshold values for acquired torques are stored and which is connected to an additional drive and/or a switching device for a transmission.

11. The drive device of claim 10, wherein the control unit is connected to a rotational speed measuring device.

12. The drive device of claim 11, wherein the evaluation unit has a power calculating unit.

13. A method for operating a machine of claim 8, wherein the connection and disconnection of an additional drive and/or of a switching device are carried out taking into account torque which is averaged over time and/or power which is averaged over time.

14. A bicycle having a drive device of claim 1.

15. A Pedelec having a drive device of claim 1.

16. An ergometer having a drive device of claim 1.

17. The drive device of claim 7, wherein the output element is a crank star.
